(19) United States
(12) Patent Application Publication
(10) Pub. No.: US 2018/0185923 A1
(43) Pub. Date: Jul. 5, 2018

(54) METHOD OF PREPARING THERMOELECTRIC MATERIAL COMPRISING IRON-SULFUR COMPOUND

(71) Applicant: UNIVERSITY OF ELECTRONIC SCIENCE AND TECHNOLOGY OF CHINA, Chengdu (CN)

(72) Inventors: Chao WANG, Chengdu (CN); Yi NIU, Chengdu (CN); Jing JIANG, Chengdu (CN); Yide CHEN, Chengdu (CN); Junfeng XIA, Chengdu (CN); Rui ZHANG, Chengdu (CN); Ting ZHOU, Chengdu (CN); Hanqing TIAN, Chengdu (CN)

(21) Appl. No.: 15/862,606

(22) Filed: Jan. 4, 2018

(30) Foreign Application Priority Data
Jan. 5, 2017 (CN) 201710007219.8

(51) Int. Cl. B22F 9/04; B22F 3/105; B22F 3/14; H01L 35/16; C01G 49/12; B22F 1/00

(52) U.S. Cl. CPC B22F 9/04; B22F 3/105; B22F 3/14; H01L 35/16; B22F 2203/11; B22F 1/0085; B22F 2003/145; B22F 2301/35; B22F 2998/10; C01G 49/12

(57) ABSTRACT

A method of preparing a thermoelectric material comprising an iron-sulfur compound, the method including: 1) weighing, grinding, and mixing an iron salt and a sulfur-containing source to obtain a mixed powder; 2) carrying out a hydrothermal reaction with the mixed powder to obtain a black precipitate; 3) washing the precipitate; 4) drying the precipitate under vacuum to obtain FeS₂ powder; 5) annealing the FeS₂ powder under inert atmosphere to obtain annealed powder, where a heating temperature is from 300° C. to 1000° C., a heating time is from 2 hours to 24 hours, and a flow rate of an inert gas is from 30 mL/min to 200 mL/min; and 6) sintering the annealed powder to obtain a thermoelectric material including an iron-sulfur compound.

### CROSS-REFERENCE TO RELATED APPLICATIONS

Pursuant to 35 U.S.C. § 119 and the Paris Convention Treaty, this application claims foreign priority benefits to Chinese Patent Application No. 201710007219.8 filed Jan. 5, 2017, the contents of which, including any intervening amendments thereto, are incorporated herein by reference. Inquiries from the public to applicants or assignees concerning this document or the related applications should be directed to: Matthias Scholl P.C., Attn.: Dr. Matthias Scholl Esq., 245 First Street, 18th Floor, and Cambridge, Mass. 02142.

### BACKGROUND OF THE INVENTION

### Field of the Invention

The disclosure relates to thermoelectric material, and more particularly to a method of preparing a thermoelectric material comprising an iron-sulfur compound.

### Description of the Related Art

Thermoelectric material can convert waste heat directly into electricity power in the absence of any moving parts or environmentally harmful fluids. Therefore, it is of great value and has great application prospects in the field of thermoelectric power generation and refrigeration.

Chalcogenide thermoelectric materials have also drawn worldwide attention for its abundant storage and outstanding performance. Iron (II) disulfide (FeS₂) has long been studied as an interesting material for solar energy conversion and electrochemical energy storage, but there are few studies about thermoelectric material. FeS₂ usually exists in two forms of pyrite and marcasite. The band gap of the former is 0.95 eV while the latter is 0.34 eV. Pyrite FeS₂ is considered as a promising thermoelectric material for its high-symmetry crystal structure, which supports the presence of highly degenerate, multi-valley electronic bands and results in a larger power factor.

FeS₂ thermoelectric material have been synthesized by ball-milling and melting method successfully, but these methods have a high demand for the reactants and are not suitable for commercial applications.

### SUMMARY OF THE INVENTION

To solve the above problems, one objective of the disclosure is to provide a method of preparing a thermoelectric material comprising an iron-sulfur compound that has relatively low production cost and is easy to operate.

In accordance with one embodiment of the invention, there is provided a method of preparing a thermoelectric material comprising an iron-sulfur compound. The method comprises the following steps:
1) weighing, grinding, and mixing an iron salt and a sulfur-containing source to obtain a mixed powder, wherein the sulfur-containing source is a mixture of sodium hyposulfite (Na₂S₂O₃) and elemental sulfur;
2) carrying out a hydrothermal reaction with the mixed powder to obtain a black precipitate;
3) washing the precipitate;
4) drying the precipitate under vacuum to obtain FeS₂ powder;
5) annealing the FeS₂ powder under inert atmosphere to obtain annealed powder, wherein a heating temperature is from 300° C. to 1000° C., a heating time is from 2 hours to 24 hours, and a flow rate of an inert gas is from 30 mL/min to 200 mL/min; and
6) sintering the annealed powder to obtain a thermoelectric material comprising an iron-sulfur compound.

In a class of this embodiment, in 1), the iron salt is ferrous sulfate.

In a class of this embodiment, a reaction temperature is from 160 and 200° C., and a reaction time is from 18 to 30 h in 2).

In a class of this embodiment, the black precipitate is washed by CS₂, deionized water, and ethyl alcohol successively in 3).

In a class of this embodiment, a drying temperature is from 50 to 100° C., and a drying time is from 4 to 10 h in 4).

In a class of this embodiment, hot-pressing sintering or discharge plasma sintering is adopted in 6), a sintering temperature is from 430 to 700° C., a pressure is from 50 to 80 mPa, and a time is from 3 to 20 min.

In this invention, FeS₂ is synthesized by hydrothermal method with low cost raw materials of iron-based and sulfur-based compounds and a little of sulfur. The compounds with different phases and different molar ratios of iron to sulfur are prepared by controlling annealing temperature in inert atmosphere. Finally, bulk samples are obtained by sintering. The method is safe, simple and cheap, with a low demand of raw materials. Consequently, the highest electrical conductivity of the products reaches up to 3.02×10⁴ S/m, and the highest power factor reaches up to 51.98 μW/cm·K².

### BRIEF DESCRIPTION OF THE DRAWINGS

FIG. 1 is a preparation process diagram of a thermoelectric material comprising an iron-sulfur compound according to one embodiment of the disclosure.

FIG. 2 is an XRD spectra of FeS₂ powder synthesized by the hydrothermal method; different symbols in the figure represent different phases of FeS₂; the XRD spectra demonstrate that FeS₂ has been synthesized successfully.

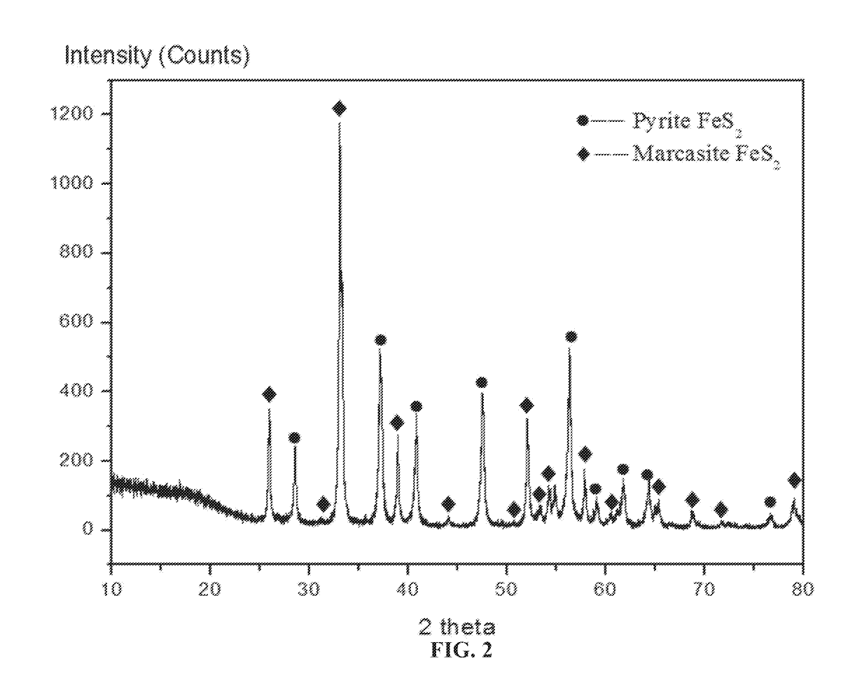

FIG. 3 is an XRD spectra of FeS₂ powder annealed at different temperatures. Compounds with different phases and different molar ratios of Fe and S are obtained at different annealing temperatures (FeS₂ annealed at 700° C. has also been studied but not presented here due to complex component).

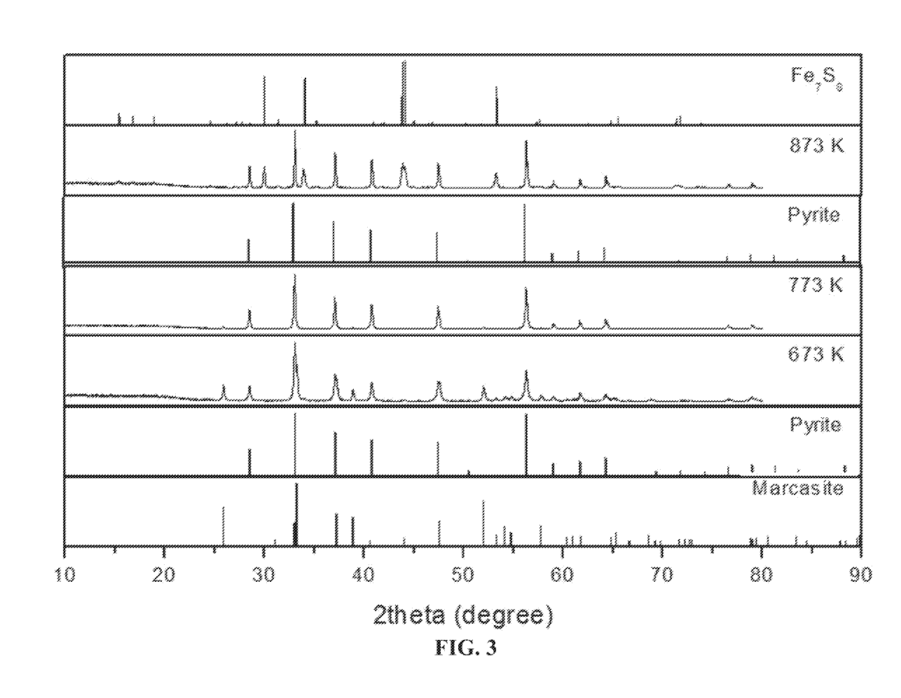

FIG. 4 is temperature dependent electrical conductivity of the thermoelectric material in Example 2, compared with reference data from Christian Uhlig. The electrical conductivities in this invention reach up to 136 S/cm at room temperature and 240 S/cm at 600 K, which are respectively much higher than reported results of 3.1 S/cm (300 K) and 7.8 S/cm (600 K).

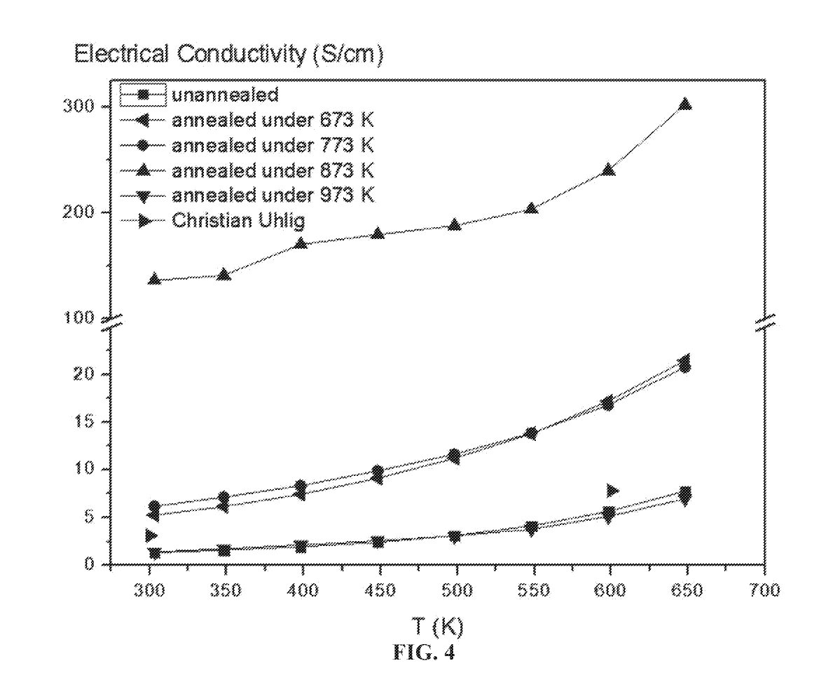

FIG. 5 is temperature dependent Seebeck coefficient of a thermoelectric material in Example 2, compared with reference data from Christian Uhlig.

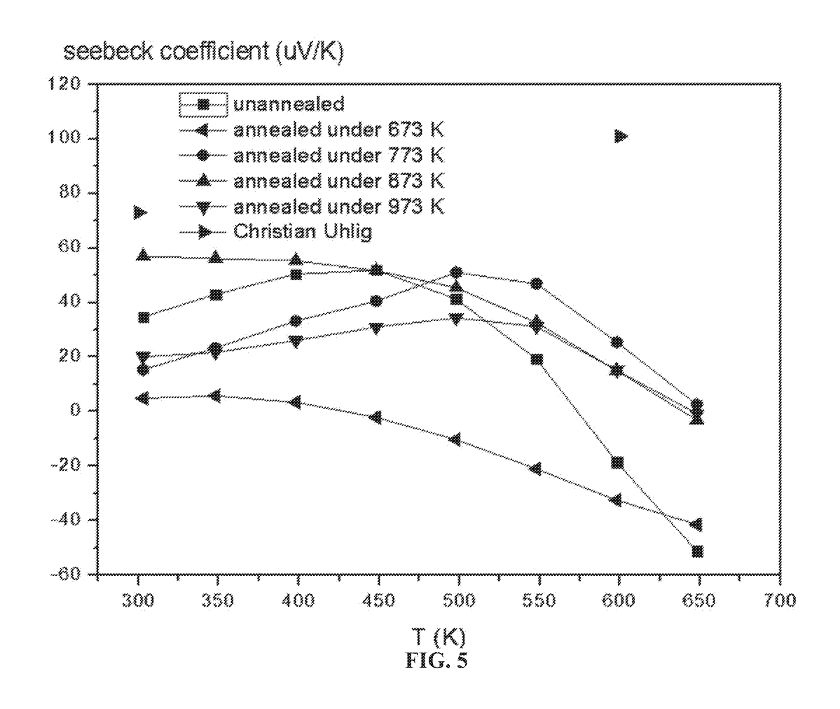

FIG. 6 is temperature dependent power factor of a thermoelectric material in Example 2, compared with reference data from Christian Uhlig.

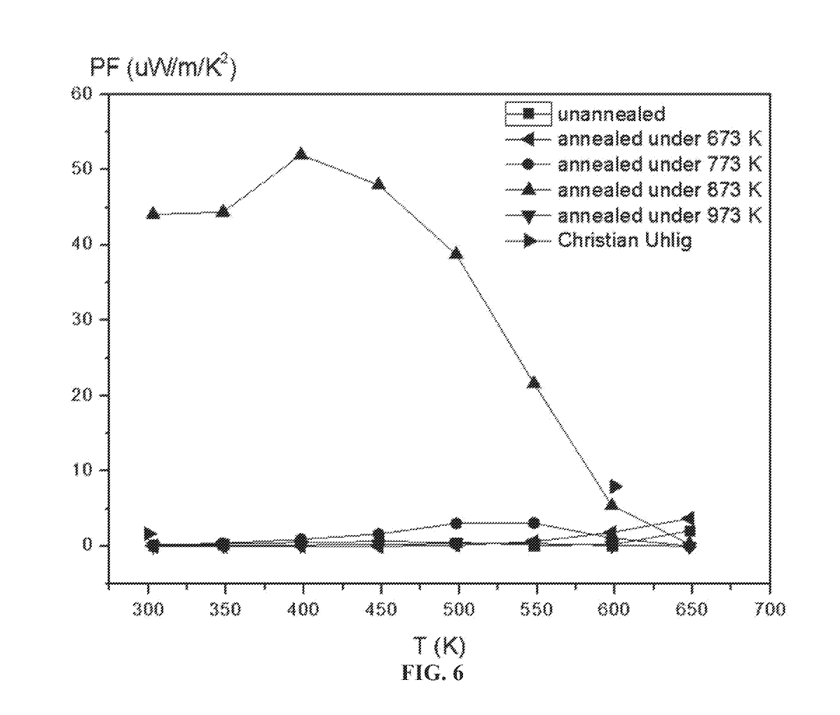

FIG. 7 is temperature dependent thermal conductivity of a thermoelectric material in Example 2, compared with reference data from Christian Uhlig. The sample synthesized by this invention possesses higher thermal conductivity, because of the weaker phonon scattering caused by larger particles.

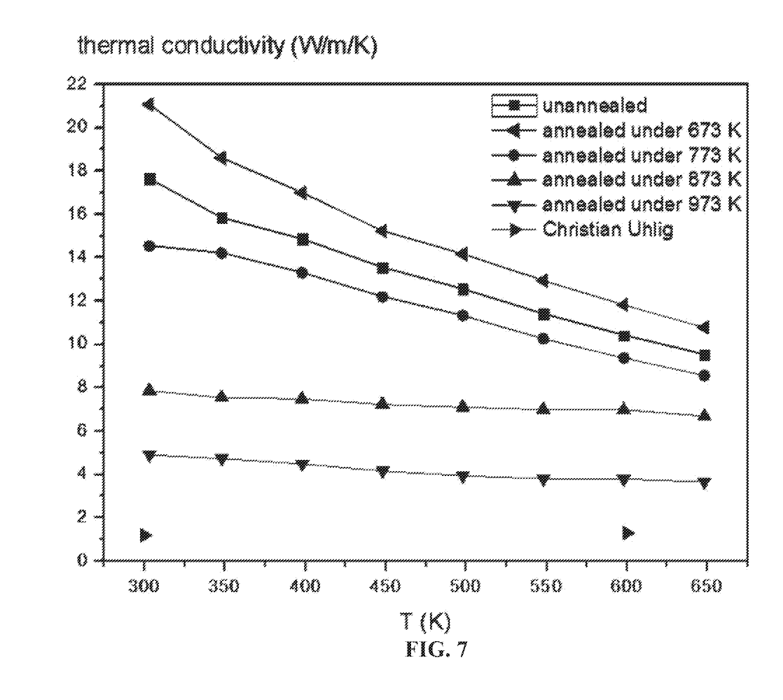

FIG. 8 is temperature dependent ZT values of a thermoelectric material in Example 2, compared with reference data from Christian Uhlig. ZT value in this invention is higher than that of reported result from Christian Uhlig at room temperature.

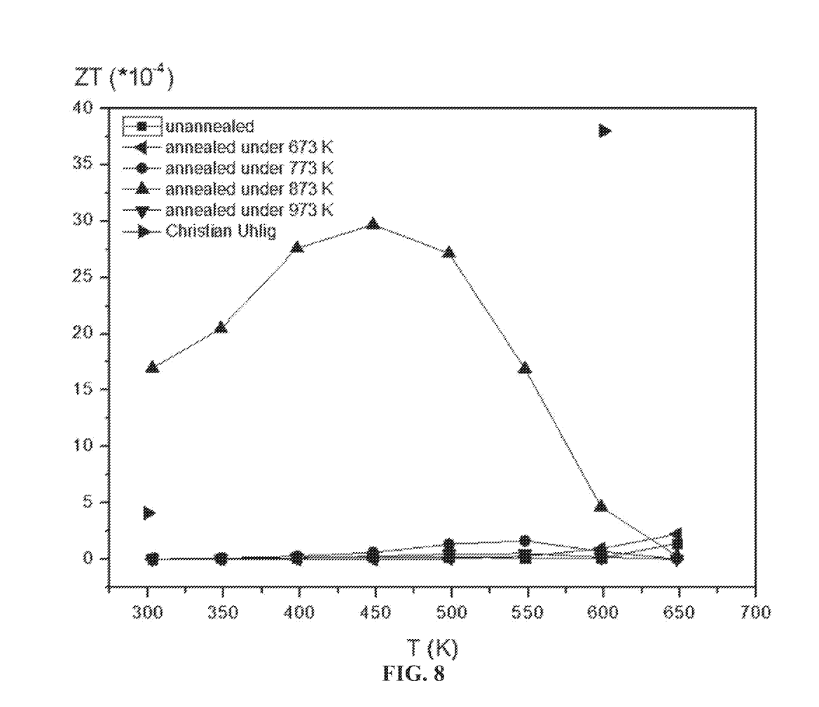

### DETAILED DESCRIPTION OF THE EMBODIMENTS

For further illustrating the invention, experiments detailing a method of preparing a thermoelectric material comprising an iron-sulfur compound are described below.

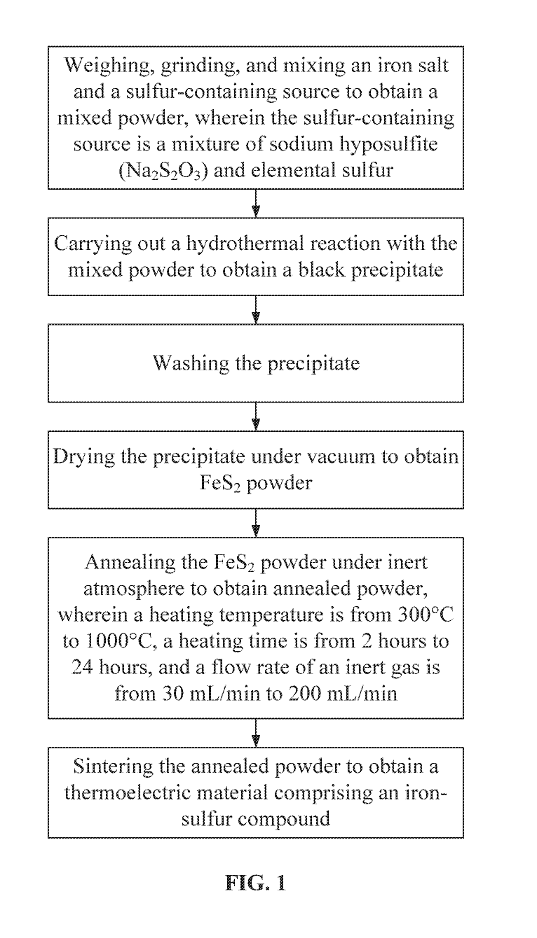

As shown in FIG. 1, this disclosure provides a method of preparing a thermoelectric material comprising an iron-sulfur compound, the method comprising:
1) weighing, grinding, and mixing an iron salt and a sulfur-containing source to obtain a mixed powder;
2) carrying out a hydrothermal reaction with the mixed powder to obtain a black precipitate, where the reaction temperature is from 160 and 200° C., and a reaction time is from 18 to 30 h;
3) washing the black precipitate using CS₂, deionized water, and ethyl alcohol successively;
4) drying the precipitate under vacuum to obtain FeS₂ powder, where the drying temperature is from 50 to 100° C., and the drying time is from 4 to 10 h;
5) annealing the FeS₂ powder under inert atmosphere to obtain annealed powder, wherein a heating temperature is from 300° C. to 1000° C., a heating time is from 2 hours to 24 hours, and a flow rate of an inert gas is from 30 mL/min to 200 mL/min; and
6) sintering the annealed powder to obtain a thermoelectric material comprising an iron-sulfur compound; specifically, hot-pressing sintering or discharge plasma sintering is adopted, a sintering temperature is from 430 to 700° C., a pressure is from 50 to 80 mPa, and a time is from 3 to 20 min.

### Example 1

Step 1: 7.6 g FeSO₄, 7.9 g Na₂S₂O₃ and 0.8 g S were weighed, and were ground sufficiently in a mortar.

Step 2: The mixture obtained in step 1 was dissolved in 50 mL deionized water and transferred into a reactor for hydrothermal reaction at 180° C. for 24 h.

Step 3: FeS₂ precipitate was obtained by filtering after the hydrothermal reactor cooled to room temperature. Then the precipitate was washed with CS₂, deionized water and ethyl alcohol several times.

Step 4: The precipitate obtained in step 3 was dried at 80° C. for 6 h under vacuum, and FeS₂ powder were obtained.

Step 5: The powder obtained in step 4 were transferred into a graphite die and densified by discharge plasma sintering at 500° C. and under 72 mPa for 10 min, then iron sulfide bulk thermoelectric material were obtained.

### Example 2

The powder was transferred into a tube furnace and heated to 500° C., 600° C., and 700° C. for 240 min respectively for annealing in step 5 of Example 1, and other operation steps are as same as that in Example 1.

Unless otherwise indicated, the numerical ranges involved in the invention include the end values. While particular embodiments of the invention have been shown and described, it will be obvious to those skilled in the art that changes and modifications may be made without departing from the invention in its broader aspects, and therefore, the aim in the appended claims is to cover all such changes and modifications as fall within the true spirit and scope of the invention.

The invention claimed is:

1. A method of preparing a thermoelectric material comprising an iron-sulfur compound, the method comprising:
1) weighing, grinding, and mixing an iron salt and a sulfur-containing source to obtain a mixed powder, wherein the sulfur-containing source is a mixture of sodium hyposulfite (Na₂S₂O₃) and elemental sulfur;
2) carrying out a hydrothermal reaction with the mixed powder to obtain a black precipitate;
3) washing the precipitate;
4) drying the precipitate under vacuum to obtain FeS₂ powder;
5) annealing the FeS₂ powder under inert atmosphere to obtain annealed powder, wherein a heating temperature is from 300° C. to 1000° C., a heating time is from 2 hours to 24 hours, and a flow rate of an inert gas is from 30 mL/min to 200 mL/min; and
6) sintering the annealed powder to obtain a thermoelectric material comprising an iron-sulfur compound.

2. The method of claim 1, wherein in 1), the iron salt is ferrous sulfate.

3. The method of claim 1, wherein a reaction temperature is from 160 and 200° C., and a reaction time is from 18 to 30 h in 2).

4. The method of claim 1, wherein the black precipitate is washed by CS₂, deionized water, and ethyl alcohol successively in 3).

5. The method of claim 1, wherein a drying temperature is from 50 to 100° C., and a drying time is from 4 to 10 h in 4).

6. The method of claim 1, wherein hot-pressing sintering or discharge plasma sintering is adopted in 6), a sintering temperature is from 430 to 700° C., a pressure is from 50 to 80 mPa, and a time is from 3 to 20 min.
